(19) United States
(12) Patent Application Publication
(10) Pub. No.: US 2009/0102049 A1
(43) Pub. Date: Apr. 23, 2009

(54) SEMICONDUCTOR DEVICE, LAYERED TYPE SEMICONDUCTOR DEVICE USING THE SAME, BASE SUBSTRATE AND SEMICONDUCTOR DEVICE MANUFACTURING METHOD

(76) Inventors: Katsumasa Murata, Nara (JP); Yuji Yano, Hiroshima (JP); Yoshiki Sota, Nara (JP)

Correspondence Address: NIXON & VANDERHYE, PC, 901 NORTH GLEBE ROAD, 11TH FLOOR, ARLINGTON, VA, 22203, US

(21) Appl. No.: 12/294,156

(22) PCT Filed: Mar. 26, 2007
(86) PCT No.: PCT/JP2007/056253

§ 371 Date: Sep. 23, 2008

(30) Foreign Application Priority Data
Mar. 27, 2006 (JP) 2006-086205

(51) Int. Cl. H01L 23/498

(52) U.S. Cl. 257/737; 257/E23.068

(57) ABSTRACT

A semiconductor device has a plurality of external connection lands arranged on a base substrate for an external connection terminal used for electrical connection with an external member. The external connection lands at different arrangement positions have different heights in accordance with a warp of the base substrate which warp the base substrate would have when mounted. Thus, even when the semiconductor device, which attains a thin thickness and a high density, is warped, it is possible to provide a semiconductor device having a high connection yield and high connection reliability between the semiconductor device and a mounting substrate and between the semiconductor devices, and it is possible to provide a layered type semiconductor device using the same, a base substrate and a semiconductor device manufacturing method.

### TECHNICAL FIELD

The present invention relates to a semiconductor device, a layered semiconductor device using the same, a base substrate and a semiconductor device manufacturing method.

More specifically, the present invention relates to a semiconductor device having a high connection yield and high connection reliability, a layered type semiconductor device using the same, base substrate and a semiconductor device manufacturing method.

### BACKGROUND ART

In recent years, as electronic apparatuses become smaller, lighter and have higher performance, there have been demands for higher density mounting of a semiconductor device. In order to meet the demands, a downsized semiconductor device and a layered semiconductor device having high density has been widely used.

The thickness of a semiconductor has been reduced by reducing the thickness and size of parts constituting a semiconductor such as a semiconductor chip and a substrate. In addition, in recent years, a layered semiconductor has been widely used for higher density of a semiconductor device.

In the layered semiconductor device having high density, an upper semiconductor device and a lower semiconductor device are stacked and electrically connected to each other, and the lower semiconductor device is connected to a mounting substrate. Thus, the layered semiconductor device enables high density mounting of a semiconductor device.

In these semiconductor devices, an insulating substrate which is a base material of a wiring board and resin which seals a semiconductor chip and the like have different material in any package configuration. Therefore, the stress is generated due to difference of coefficient of thermal expansion of the respective materials when the semiconductor is mounted. When the semiconductor device has a lead frame, the stress can be effectively reduced by the lead frame.

However, when the semiconductor device does not have a lead frame, it is difficult to reduce the stress. Therefore, the stress is applied to the external connection terminal. This causes a loose connection between an external terminal and a connection electrode (land) on a printed circuit board.

For the purpose of preventing the loose connection, Patent Document 1, for example, discloses a semiconductor device 100 in which the height of external connection terminals 101 becomes higher in outer areas of the semiconductor device 100, as shown in FIG. 6.

[Patent Document 1]

Japanese Unexamined Patent Application Publication Tokukaihei No. 2002-164473 (published on Jun. 7, 2002)

### DISCLOSURE OF INVENTION

However, with the conventional arrangement, it is difficult to sufficiently reduce the thickness and increase the density of the semiconductor device.

Specifically, the thickness of the semiconductor device is reduced by reducing the thickness of a semiconductor chip, a sealing resin and a base substrate and by lowering the height of an external connection terminal. However, the reduction in thickness enlarges the difference of coefficient of linear expansion of respective member constituting the semiconductor device whose thickness is reduced. Therefore, it is difficult to control an amount of warping of the semiconductor device.

As shown in FIG. 7, when the semiconductor device is mounted on a mounting substrate, a small warp of the semiconductor device causes a loose connection even at a room temperature because the height of the external connection terminal is reduced.

The density of the semiconductor device is increased, for example, by stacking the semiconductor devices.

A conventional layered type semiconductor device 200 is shown in FIG. 7. The layered type semiconductor device is obtained by stacking semiconductor devices 210 and 220 whose thickness is reduced. In the layered type semiconductor device 200, a semiconductor chip 204 is provided on a base substrate 203 via an adhesive layer 205. Furthermore, external connection lands 201 are formed on a surface of the base substrate 203 where the semiconductor chip 204 is provided and a reverse surface thereof.

External connection terminals 202 are formed on the external connection lands 201 formed on the surface where the semiconductor chip 204 is provided. Furthermore, the external connection terminals 202 are connected to the semiconductor device 210 via the external connection lands 201 formed on the external connection terminals 202.

The external connection terminals 202 are formed on the external connection lands 201 formed on the reverse surface. Furthermore, the external connection terminals are connected to the semiconductor device 210 via the external connection lands 201 formed on the external connection terminals 202.

The semiconductor devices 210 and 220 are thin semiconductor devices, and thus the members thereof are reduced in thickness. This enlarges the difference of coefficient of linear expansion of the respective members. Therefore, it is difficult to control an amount of the warping of the semiconductor device at a room temperature.

The semiconductor devices 210 and 220 are mounted on the substrate and stacked by applying heat in a reflow process. The stress applied to the semiconductor devices 210 and 220 is stronger than the stress at a room temperature due to the difference of coefficient of thermal expansion of the respective material used in the semiconductor devices. The stress causes warps between the semiconductor devices 210 and 220 and between the semiconductor device 220 and the mounting substrate 230. Because the height of the external connection terminals is reduced, connection between the semiconductor devices 210 and 220 is partially cut. This means that a loose connection is caused.

As described above, the conventional semiconductor device causes a problem that a loose connection is easily caused in the semiconductor device and the layered type semiconductor device due to a room temperature or heat applied in the reflow process. This means that the conventional semiconductor device has low connection reliability. Further, this means that the conventional semiconductor device has a low connection yield in a manufacturing process. This is a significant problem in providing a semiconductor device.

It should be noted that in order to solve the problem, the semiconductor device 100 of the Patent Document 1 is characterized in that the external connection terminals 101 positioned further from the center of the semiconductor device 100 have higher heights. Therefore, even if the semiconductor device 100 is warped due to the stress, a loose connection is not caused between the external connection terminals 101 and the mounting substrate.

With the above arrangement, it is possible to prevent a loose connection. However, the semiconductor device is characterized in that the external connection terminals positioned further from the center of the semiconductor device have higher heights. The external connection terminals are formed by employing a printing method using a screen mask. However, the printing method is not a popular method in a process of manufacturing a semiconductor device.

Further, the direction in which the semiconductor device is warped varies due to the coefficient of linear expansion of the respective materials. This means that there is a case in which the external connection terminals must be made higher towards the center, unlike the semiconductor device 100. Further, this method requires equipment investments, and therefore manufacturing cost wilt be high.

When it comes to actual production, such problems make it difficult to sufficiently reduce the thickness and increase the density of the semiconductor device. Therefore, development of a new process is required.

The present invention was accomplished in view of the above problems. It is an object of the present invention to provide a semiconductor device having a high connection yield and high connection reliability between the semiconductor device and a mounting substrate and between the semiconductor devices even when the semiconductor device, which attains a thin thickness and a high density, is warped, and to provide a layered type semiconductor device using the same, a base substrate and a semiconductor device manufacturing method.

In order to attain the above object, a semiconductor device of the present invention includes a plurality of external connection lands arranged on a base substrate for an external connection terminal used for electrical connection with an external member, the external connection lands at different arrangement positions having different heights in accordance with one of or both of a warp of the base substrate and a warp of the semiconductor device which warp the base substrate or semiconductor device would have when mounted.

With the above arrangement, the height of the external connection lands is adjusted in advance in accordance with one of or both of a warp of the base substrate and a warp of the semiconductor device when mounted. Therefore, even when one of or both of the base substrate and the semiconductor device is warped, a loose connection can be prevented between the semiconductor device and the base substrate and between the semiconductor devices. That is, it is possible to provide a semiconductor device having a high connection yield and high connection reliability.

When the external connection lands are formed on a reverse surface of the base substrate, the semiconductor device of the present invention has a higher connection yield and higher connection reliability between the reverse surface and another semiconductor device or the mounting substrate.

In the semiconductor device of the present invention, the external connection lands are preferably formed on the reverse surface of the base substrate.

When the external connection lands are formed on a surface of the base substrate where the semiconductor chip is provided, the semiconductor device of the present invention has a higher connection yield and higher connection reliability between the surface where the semiconductor chip is provided and another semiconductor device or the mounting substrate.

In the semiconductor device of the present invention, the external connection lands are preferably formed on the surface of the base substrate where the semiconductor chip is provided.

With the above arrangement, the external connection lands are formed on the surface where the semiconductor chip is provided, and therefore it is possible to stack the semiconductor devices.

In the semiconductor device of the present invention, the external connection lands are preferably formed of a copper foil pattern and by plating.

When the external connection lands are formed of a copper foil pattern and by plating, it is possible to use existing facilities in forming the external connection lands.

In order to attain the above object, the semiconductor device of the present invention includes a plurality of external connection lands arranged on a base substrate for an external connection terminal used for electrical connection with an external member, the external connection terminal being formed on at least one of the plurality of external connection lands and not being formed on all of the plurality of external connection lands.

Further, the semiconductor device of the present invention includes a plurality of external connection lands arranged on a base substrate for an external connection terminal used for electrical connection with an external member, the external connection terminals being formed on at least one of the plurality of external connection lands and not being formed on all of the plurality of external connection lands, the external connection terminals at different arrangement positions having different heights in accordance with a warp of the base substrate which warp the base substrate would have when mounted.

According to the above arrangement, the external connection terminal is formed on at least one of the terminals can be improved.

In the semiconductor device of the present invention, the external connection terminals are preferably made from a flux.

When the external connection terminals are made from a flux, the semiconductor device can be made more compact when mounted. This produces the effect that the external connection terminals can be made lower, and the position where the semiconductor device is mounted can be made lower.

In the semiconductor device of the present invention, the external connection terminals are preferably made from a wire bump.

When the external connection terminals are made from a wire bump, it is possible to form stable bump shape and height, and further it is possible to use an existing facility without the need for equipment investments.

In the semiconductor device of the present invention, a plurality of wire bumps are preferably formed on the external connection lands.

It should be noted that the plurality of wire bumps may be provided one-dimensionally or may be provided three-dimensionally. When the plurality of wire bumps are formed on at least one of the external connection lands, it is possible to adjust the height of the wire bumps.

In order to solve the above problems, a layered type semiconductor device of the present invention is characterized in that the semiconductor device and another semiconductor are stacked so as to be electrically connected to each other.

According to the above arrangement, the semiconductor device and another semiconductor are stacked so as to be electrically connected to each other. This makes it possible to provide a layered type semiconductor device using another semiconductor device.

In order to solve the above problems, the layered type semiconductor device of the present invention is characterized in that the semiconductor devices are stacked so as to be electrically connected to each other.

According to the above arrangement, the semiconductor devices are stacked so as to be electrically connected to each other. This makes it possible to provide a layered type semiconductor device.

In order to solve the above problems, the base substrate of the present invention is a base substrate on which a plurality of external connection lands arranged for an external connection terminal used for electrical connection with an external member, the external connection lands at different arrangement positions having different heights in accordance with a warp of the base substrate and a warp of the semiconductor device which warp the base substrate or semiconductor device would have when mounted.

According to the above arrangement, it is possible to provide a base substrate of a semiconductor device in which the external connection lands are uniformly arranged when the semiconductor is mounted.

In the base substrate of the present invention, the external lands are preferably formed of a copper foil pattern and by plating.

When the external lands are formed of a copper foil pattern and by plating, it is possible to use existing facilities in forming the external connection lands.

In order to solve the above problems, a method for manufacturing the semiconductor device of the present invention includes the steps of (i) forming each of the external connection lands by plating and (ii) stacking, by plating with the use of a mask, each of the external connection lands on the formed external connection lands, the mask having openings in positions where the external connection lands are formed.

With the above arrangement, it is possible to adjust the height of the external connection lands by plating. Because the height is adjusted by a plating process, it is possible to use an existing facility. Therefore, investments for a new facility are not required.

In order to solve the above problems, a method for manufacturing the semiconductor device of the present invention includes the steps of (i) forming each of the external connection lands uniformly so as to have a predetermined thickness by etching a copper foil and (ii) stacking, by plating with the use of a mask, each of the external connection lands on each of the external connection lands which is formed so as to have a predetermined thickness, the mask having openings in positions where the external connection lands are formed.

With the above arrangement, it is possible to adjust the height of the external connection lands by etching. The adjustment by etching makes it possible to form the external connection lands uniformly so as to have the predetermined thickness. Further, it is possible to use existing facilities, and there is no need for investments for a new facility.

In order to solve the above problems, a method for manufacturing the semiconductor device of the present invention is a method for manufacturing the semiconductor device in which a plurality of external connection terminals are arranged on a base substrate for an external connection terminal used for electrical connection with an external member, the external connection lands at different arrangement positions having different heights in accordance with a warp of the base substrate and a warp of the semiconductor device which warp the base substrate or semiconductor device would have when mounted, each of the external connection terminals being formed by a wire bonding method at a step of connecting a semiconductor chip and the base substrate by the wire bonding method.

According to the above arrangement, it is possible to form the external connection terminal on a favorite external connection land and to freely and precisely adjust the height of the external connection terminal.

In the method for manufacturing the semiconductor device of the present invention, the external connection terminal made from a plurality of wire bumps are preferably formed on at least one of the external connection lands.

When the external connection terminal made from the plurality of wire bumps are formed on at least one of the external connection lands, it is possible to provide a semiconductor device in which the height of complex wire bumps can be adjusted.

In the method for manufacturing the semiconductor device of the present invention, it is possible to form at least one of the external connection lands on a reverse surface of the base substrate. When the external connection lands are formed on the reverse surface of the base substrate, it is possible to provide a semiconductor device in which the reverse surface can be connected to the semiconductor device or the mounting substrate.

In the method for manufacturing the semiconductor device of the present invention, it is possible to form at least one of the external connection lands on a surface of the base substrate where the semiconductor chip is provided. When the external connection lands are formed on the surface of the base substrate where the semiconductor chip is provided, it is possible to form the external connection terminal while forming the wire on the base substrate. Further, because the external connection lands are formed on the surface where the semiconductor chip is provided, it is possible to provide a semiconductor device in which stacking with another semiconductor device is possible.

Additional objects, features, and strengths of the present invention will be made clear by the description below. Further, the advantages of the present invention will be evident from the following explanation in reference to the drawings.

### BRIEF DESCRIPTION OF DRAWINGS

FIG. 1 shows an embodiment of a semiconductor device of the present invention and is a cross-sectional view showing an arrangement of the semiconductor device.

FIG. 2 is a cross-sectional view of an arrangement of a layered type semiconductor device which is obtained by stacking the semiconductor devices.

FIG. 3 shows another embodiment of the semiconductor device of the present invention and is a cross-sectional view showing an arrangement of the semiconductor device.

FIG. 4 is a plan view showing external connection terminals formed on an external connection land of the semiconductor device.

FIG. 5 is a side view showing the external connection terminals formed on the external connection land of the semiconductor device.

FIG. 6 is a cross-sectional view showing an arrangement of a conventional semiconductor device.

FIG. 7 is a cross-sectional view showing an arrangement of a conventional layered type semiconductor device.

### REFERENCE NUMERALS

1, 11: external connection land
1, 2a, 2b, 12: external connection terminal
3, 13: base substrate
4, 14: semiconductor chip
5, 15: adhesive layer
6, 16: wire
7, 17: scaling resin
10, 30, 50: semiconductor device (external member)
20: layered type semiconductor device
40: mounting substrate (external member)

### BEST MODE FOR CARRYING OUT THE INVENTION

### Embodiment 1

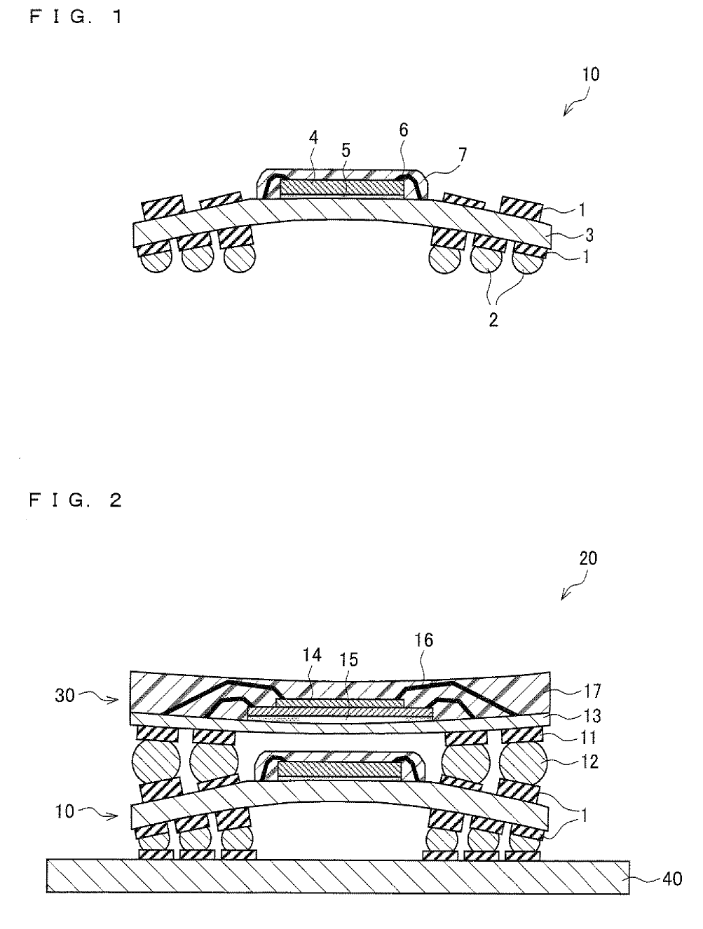

One embodiment of the present invention is described below with reference to FIGS. 1 and 2. It should be noted that the present invention is not limited to this.

As shown in FIG. 1, a semiconductor device 10 of the present embodiment includes a semiconductor chip 4 mounted on a middle surface of a base substrate 3 via an adhesive layer 5. The base substrate 3 and the semiconductor chip 4 are electrically connected with each other via a wire 6. The semiconductor chip 4 and the wire 6 are sealed by a sealing resin 7. External connection lands 1 for stacking another semiconductor device are formed on the periphery of the semiconductor chip and on the outer edge area of the semiconductor device 10.

Further, the external connection lands 1 are formed also on a reverse surface of the base substrate 3. External connection terminals 2 are formed on these external connection lands 1. The external connection lands 1 formed on the both surface of the base substrate 3 are arranged in an area array pattern.

The base substrate 3 may be made from a conventionally known material in semiconductor device manufacture. Specifically, the base substrate 3 may be made from an insulating material such as glass epoxy and polyimide. The thickness of the base substrate 3 is not limited. However, the base substrate preferably has the thickness of approximately 0.05 mm to 0.5 mm.

The external connection lands 1 of the present embodiment may be made from a material generally used for an external connection lands. However, the external connection lands 1 are preferably formed by plating. The use of plating allows that the external connection lands can be formed by using existing facilities.

The external connection lands 1 are formed on the both surfaces of the base substrate 3, but are not limited to this. The external connection lands 1 may be formed on the surface where the semiconductor chip 4 is provided. This enables a higher connection yield and higher connection reliability between the surface where the semiconductor chip 4 is provided and another semiconductor device.

Further, the external connection lands 1 may be formed on the reverse surface of the base substrate which is reverse to that surface of the base substrate on which a semiconductor chip 4 is provided. This enables a higher connection yield and higher connection reliability between the surface where the semiconductor chip 4 is provided and another semiconductor device.

A plurality of the external connection lands 1 are formed on the base substrate 3. As shown in FIG. 1, for example, four external connection lands 1 are formed on the surface of the base substrate 3 where the semiconductor chip 4 is provided, and six external connection lands 1 are formed on the reverse surface of the base substrate 3. However, the number of the external connection lands are not limited to this, provided that the arrangement position is set in accordance with a warp of the base substrate 3 and a warp of the semiconductor device 10.

Further, the position where the external connection lands are provided is not limited, too. However, the semiconductor chip 4 is positioned on the middle of the base substrate 3. Therefore, the external connection lands are preferably provided from the outer area of the base substrate 3.

The external connection lands 1 of the semiconductor device 10 of the present embodiment have different heights at different arrangement positions on the base substrate 3. The lengths are determined on the basis of the stress generated due to difference of coefficient of thermal expansion of the respective member when mounted or stacked.

A material of the external connection terminals 2 is not limited. The external connection terminals can be made from a material generally used for manufacture of the semiconductor device 10. Further, a wiring pattern (not shown) made of an electrically conductive material is formed on the both sides of the base substrate 3. The electrically conductive material is not limited, provided that the material has high conductivity. The wiring pattern is preferably made of copper. The thickness of the electrically conductive material is not limited. However, the thickness of approximately 10 to 20 μm is preferable.

The formation of the wiring pattern on the base substrate 3 is performed in such a manner that a solder resist material for protecting the wiring pattern is applied on this electrically conductive material, and openings are formed to expose only an external terminal (not shown), and a wire bond terminal section (not shown), and the like therethrough.

The semiconductor chip 4 is not limited, and an appropriate material is selected according to the use. The thickness of the semiconductor chip 4 is not limited, too. However, the semiconductor chip preferably has the thickness in a range of 0.05 mm to 0.2 mm.

The adhesive layer 5 for sticking the semiconductor chip 4 on the base substrate 3 can be made from a material generally used for semiconductor device manufacture. The thickness of the adhesive material is not limited. However, the adhesive material preferably has the thickness in a range of 5 to 00 μm.

For example, the semiconductor chip 4 is adhered onto the base substrate 3 by sticking an insulating sheet material or the like, as the adhesive layer 5, onto a side of the semiconductor chip 4 which side faces the base substrate 3. Further, for example, the semiconductor chip 4 is adhered onto the base substrate 3 by applying a liquid adhesive, as the adhesive layer 5, onto a side of the semiconductor chip 4 which faces the substrate.

The wire 6 is not limited, provided that the wire 6 can electrically connect the base substrate 3 and the semiconductor chip 4. A wire generally used for manufacture of a semiconductor device can be used.

The thickness of the sealing resin 7 is not limited. It should be noted that the thickness of the sealing resin 7 differs depending on the thickness of the semiconductor chip 4 and whether the semiconductor device 10 is stacked or not. When the semiconductor device 10 is stacked, if the external connection lands are formed at a pitch of 0.65 mm and less or 0.5 mm and more, it is preferable that the thickness of the sealing resin 7 is 0.3 mm and less or 0.15 mm and more.

In the semiconductor device 10, the height of the external connection lands 1 formed on the both sides of the base substrate 3 is adjusted depending on arrangement positions in accordance with a warp of the base substrate 3 and a warp of the semiconductor device 10 which warp the base substrate 3 or semiconductor device 10 would have when mounted, the warps being generated at a room temperature or by application of heat in the reflow process. Therefore, even if the stress is applied to the semiconductor device 10 when mounted, non-uniformity of the height of the external connection lands is small after the semiconductor device is mounted. Therefore, a loose connection is hardly caused even if the position of the external connection terminals 2 is considerably changed by the stress when mounted.

The following explains the case where the semiconductor device 10 is layered. FIG. 2 is a cross-sectional view of a layered type semiconductor device 20.

In the layered type semiconductor device 20, the semiconductor device 10 and a semiconductor device 30 are stacked and are mounted on a mounting substrate 40. The semiconductor device 30 is a conventional semiconductor device, in which a semiconductor chip 14 is mounted on a base substrate 13 having external connection lands 11 via an adhesive layer 15, and the base substrate 13 and the semiconductor chip 14 are electrically connected with each other via a wire 16 and are sealed by a sealing resin 17. The external connection lands 11 on the base substrate 13 have the same height and are arranged in an area array pattern. The semiconductor device 10 and the semiconductor device 30 are stacked via external connection terminals 12.

The height of the external connection lands 1 formed on the both sides of the base substrate 3 is adjusted depending on the arrangement position according to how much the semiconductor device 10 and the semiconductor device 30 warp at a room temperature or by application of heat in the reflow process.

The stress is applied to the semiconductor devices 10 and 30 in the reflow process performed when the semiconductor devices 10 and 30 are stacked. However, because the height is adjusted in advance, the external connection lands 1 formed on the both sides of the base substrate 3 have almost the same height.

Therefore, the disconnection between the external connection lands 1 and the external connection terminals 2 is hardly caused by the stress. According to the layered type semiconductor device 20 of the present embodiment, it is possible to prevent a loose connection and to improve connection reliability. Further, it is possible to improve a connection yield.

Further, in a semiconductor device called land grid array (LGA) (not shown), a solder paste or a flux is used as an external connection terminal. The height of the external connection terminal is very low, and the thickness of the semiconductor device is further reduced. Therefore, a loose connection is easily caused by a warp of the substrate and the semiconductor. Therefore, the invention of the present embodiment can be effectively applied to an LGA semiconductor device.

It should be noted that explained above is an exemplary case in which the semiconductor device 10 and the semiconductor device 30 are stacked. The present invention is not limited to this. Another arrangement is possible in which the semiconductor devices 10 are stacked, or the semiconductor device 10 and another semiconductor device are stacked. If the semiconductor device 10 including the external connection lands 1 having different heights depending on the arrangement position is stacked or mounted, a similar effect to the present embodiment can be obtained.

### Embodiment 2

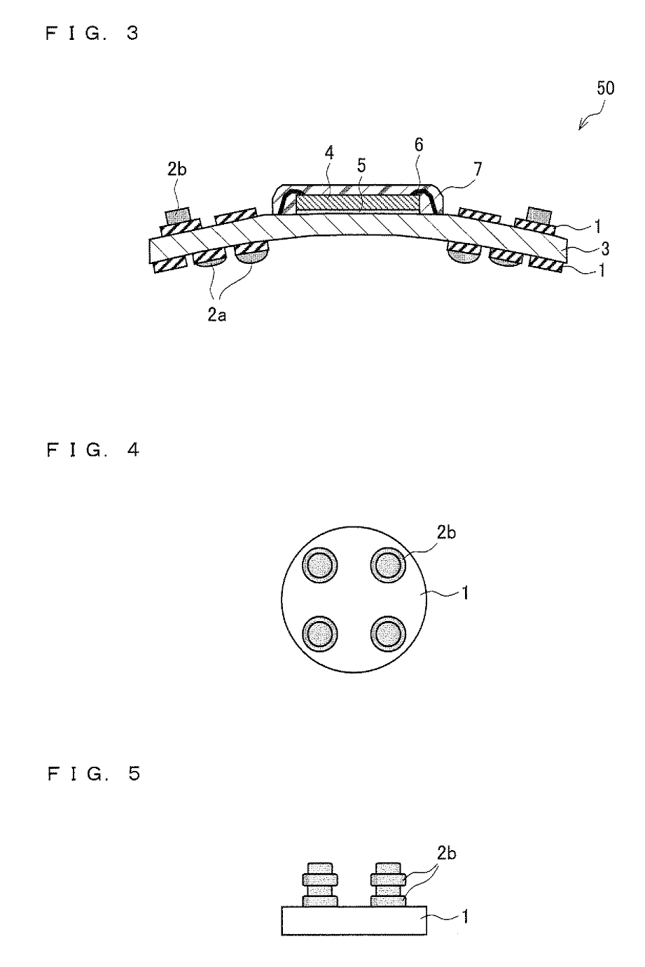

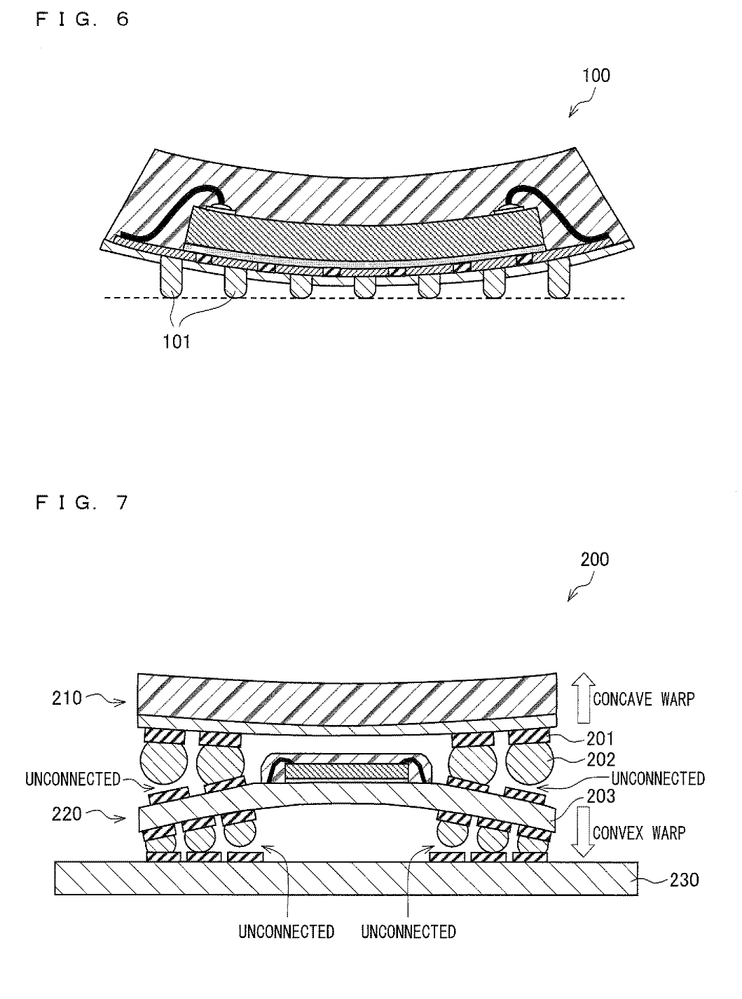

Another embodiment of the present invention is described below with reference to FIGS. 3 through 5. It should be noted that for the easy explanation, constituent members which are identical with those explained in Embodiment 1 are given identical reference numerals and are not explained repeatedly.

Examples of the semiconductor device of the present invention includes a semiconductor device 50 in which the external connection lands 1 are formed on the both sides of the base substrate 3, as shown in FIG. 3. At least one external connection terminal 2a or external connection terminal 2b is formed on the external connection land 1.

The height of the external connection lands 1 formed on the base substrate 3 is not adjusted depending on the arrangement position. Each of the external connection lands 1 has the same height.

At least one external connection terminal 2a or external connection terminal 2b is formed on the external connection land 1. Therefore, the position where the external connection terminal 2a and the external connection terminal 2b are formed is not limited to the position shown in FIG. 3.

In FIG. 3, the external connection terminal 2a is formed on the reverse surface of the base substrate 3, and the external connection terminal 2b is formed on the surface of the base substrate 3 where the semiconductor chip 4 is provided. However, the arrangement position of the external connection terminal 2a and the external connection terminal 2b is not limited to the position shown in FIG. 3.

The external connection terminals 2a and 2b may be formed on the surface where the semiconductor chip 4 is provided. In the surface where the semiconductor chip is provided, when the semiconductor device is stacked, the high stress is applied to the semiconductor device 50, and a loose connection is easily caused. When the external connection terminals 2a and 2b whose height can be precisely adjusted are formed on this surface, even the high stress hardly causes a loose connection.

For example, the external connection terminal 2a may be formed of a flux. A material for the flux is not limited. The flux can be made of a material generally used in semiconductor device manufacture.

When the flux is used as a material of the external connection terminal 2a, the size of the external connection terminal can be reduced when mounted and stacked. Therefore, the flux is effective at reducing the height of the external connection terminal and reducing the mounting height of the semiconductor device. That is, the flux is effective at reducing the thickness of the semiconductor device.

For example, the external connection terminal 2a may be formed of a solder paste. Materials constituting the solder paste are not limited. Materials generally used in semiconductor device manufacture can be used.

When the solder paste is used, the mounting height of the semiconductor device is higher, as compared to the case of using the flux described below. However, the connection reliability can be improved, as compared to the case of using the flux.

As for a method for forming the external connection terminal 2a, it is possible to select whether or not the external connection terminal 2a is formed on the external connection land by changing an arrangement and a diameter of a nozzle for transferring the solder paste and the flux. Further, it is possible to freely control the amount and height of the paste or the flux.

When the external connection terminal 2a is formed on the surface of the base substrate 3 where the semiconductor chip 4 is provided, it is possible to mount the semiconductor chip 4 on the base substrate 3 and to form the external connection terminal 2a at the same time. Therefore, there is no need for a step of forming the external connection terminal 2a. A process for manufacturing a semiconductor device can be simplified.

The external connection terminal 2b is formed of a wire bump. A material for the external connection terminal 2b is not limited. However, a material such as gold and silver can be used.

A plurality of the external connection terminals 2b may be formed on one external connection land 1. As shown in FIG. 4, a plurality of the external connection terminals 2b can be formed on one plane on one external connection land 1. Further, as shown in FIG. 5, a plurality of the external connection terminals 2b can be stacked on one external connection land 1.

By forming a plurality of external connection terminals 2b, it is possible to form an external connection terminal 2b having a complex shape. In the semiconductor device 50, the height of the external connection land 1 is changed by the stress generated at a room temperature or application of heat in the reflow process. However, even if the height of the external connection land 1 is changed, a loose connection of the external connection land 1 is hardly caused because the external connection terminal 2a or the external connection terminal 2b is formed on the external connection land 1. Further, this effect can be obtained regardless to which side of the base substrate 3 the external connection terminal 2a or the external connection terminal 2b is formed on.

Further, it is possible to stack the semiconductor device 50 and the conventional semiconductor device or the semiconductor devices 50. Further, it is possible to stack the semiconductor device 50 and the semiconductor device 10 shown in FIG. 1. Even in this case, the same effect can be obtained.

### Embodiment 3

The following explains a method for manufacturing a semiconductor device of another embodiment of the present invention.

(Step of Forming Each of the External Connection Lands by Using Plating)

This step is a step of forming the external connection lands having different heights by using plating.

A material for plating is not limited. However, a material such as copper and nickel can be used.

When each of the external connection lands is formed by using copper, there is an advantage that it is unnecessary to perform a plating treatment as a pretreatment at a step of stacking each of the external connection lands by using plating. The step of stacking each of the external connection lands will be described below.

(Step of Stacking Each of the External Connection Lands by Using Plating)

This step is a step of stacking predetermined external connection lands by using plating and adjusting the height of the external connection lands. If necessary, this step includes a step of performing a plating treatment on whole of the external connection lands as a pretreatment. For example, when nickel is used for plating, nickel plating is performed on all of the external connection lands as a pretreatment.

When copper is used for plating, it is unnecessary to perform such pretreatment because plating can be performed directly on copper wiring on the base substrate.

The step of stacking each of the external connection lands by using plating includes a step of forming solder resist and the like as a mask after formation of a wiring pattern. At the same time as the solder resist and the like are formed, plating is performed on the external connection lands in such a manner that openings for exposing the predetermined external connection lands are formed. By performing plating, the thickness of the predetermined external connection lands is increased. Therefore, it is possible to adjust the height of the external connection lands.

With the above step, it is possible to realize a semiconductor device in which the external connection lands at different arrangement positions have different heights in accordance with a warp of the base substrate and a warp of the semiconductor device which warp the base substrate or semiconductor device would have when mounted. This manufacturing method has an advantage that there is no need for investments for new facilities because the manufacturing process after making of the base substrate is the same as the conventional plating process.

(Step of Uniformly Forming Each of the External Connection Lands by Etching a Copper Foil so as to Have a Predetermined Thickness)

Further, instead of the step of forming each of the external connection lands 1 by using plating, it is possible to perform a step of uniformly forming each of the external connection lands by etching a copper foil so as to have a predetermined thickness (hereinafter referred to as (etching step)), and then perform the step of stacking each of the external connection lands by plating.

The etching step is a step of uniformly forming each of the external connection lands by etching a copper foil so as to have a predetermined thickness. The etching of a copper foil makes it possible to uniformly form each of the external connection lands so as to have a predetermined thickness. Because each of the external connection lands is formed by using a copper foil, it is unnecessary to perform the plating treatment as a pretreatment at the step of stacking each of the external connection lands by using plating.

### Embodiment 4

The following explains a method for manufacturing a semiconductor device of another embodiment of the present invention.

(Step of Forming Each of the External Connection Terminals by a Wire Bonding Method)

This step is a step of forming the external connection terminal on the external connection land by using a wire bonding method. As for the wire bonding method, a conventionally known method such as a thermocompression wire bonding method, a supersonic wire bonding method and a supersonic/thermocompression wire bonding method can be used.

For example, the external connection terminal 2b as shown in FIG. 3 is formed by using the supersonic/thermocompression wire bonding method. The external connection terminal 2b can be formed by applying heat and pressure on a ball formed at an end section of a capillary while applying a supersonic wave to the external connection land 1.

In this step, it is possible to freely connect the external connection terminal 2b depending on the arrangement position of the external connection lands 1, and to adjust the height of the external connection terminal 2b. This makes it possible to provide the semiconductor device 50 in which each of a plurality of external connection terminals 2b has a different height. This step does not require development of a new process and investments for new facilities because the conventional wire bonding method can be used.

As shown in FIG. 4, the plurality of external connection terminals 2b can be one-dimensionally formed on one external connection land 1. Further, as shown in FIG. 5, the plurality of external connection terminals 2b can be three-dimensionally formed on one external connection land 1. This makes it possible to form a complex external connection terminal 2b and to provide a semiconductor device 50 in which the height of the complex external connection terminal 2b can be adjusted.

The external connection terminals 2b may be formed on the surface of the base substrate 3 where the semiconductor chip 4 is provided, or may be formed on the reverse surface of the base substrate 3. When the external connection terminals 2b are formed on the reverse surface of the base substrate 3, it is possible to provide a semiconductor device in which connection between the reverse surface and another semiconductor device or mounting substrate.

When the external connection terminals 2b are formed on the surface of the base substrate 3 where the semiconductor chip 4 is provided, it is possible to form the external connection terminals 2b on the external connection lands 1 at the same time as the wire 6 is formed. Further, because the external connection lands 1 are formed on the surface where the semiconductor chip is provided, it is possible to provide a layered type semiconductor device in which another semiconductor device can be stacked.

The present invention is not limited to the description of the embodiments above, but may be altered by a skilled person within the scope of the claims. An embodiment based on a proper combination of technical means disclosed in different embodiments is encompassed in the technical scope of the present invention. For example, regardless of the arrangement position of the external connection lands 1 and the surface of the base substrate 3 where the external connection lands 1 are formed, a plurality of embodiments disclosed in the Embodiment 1 and Embodiment 2 can be applied to an semiconductor device.

As described above, in the semiconductor device of the present invention, the external connection lands at different arrangement positions have different heights in accordance with a warp of the base substrate and a warp of the semiconductor device which warp the base substrate or semiconductor device would have when mounted.

As described above, in the semiconductor device of the present invention, the external connection terminals are formed on at least one of the plurality of external connection lands, the external connection terminals at different arrangement positions having different heights in accordance with a warp of the base substrate and a warp of the semiconductor device which warp the base substrate or semiconductor device would have when mounted.

As described above, in the layered type semiconductor device of the present invention, the semiconductor devices of the present invention are stacked, or the semiconductor device and another semiconductor device are stacked.

As described above, in the base substrate of the present invention, the external connection lands at different arrangement positions have different heights in accordance with a warp of the base substrate and a warp of the semiconductor device which warp the base substrate or semiconductor device would have when mounted.

As described above, a method for manufacturing the semiconductor device of the present invention includes the steps of (i) forming each of the external connection lands by using plating and (ii) stacking, by plating with the use of a mask, each of the external connection lands on the formed external connection lands, the mask having openings in positions where the external connection lands are formed.

As described above, a method for manufacturing the semiconductor device of the present invention includes the steps of (i) forming each of the external connection lands uniformly so as to have a predetermined thickness by etching a copper foil and (ii) stacking, by plating with the use of a mask, each of the external connection lands on each of the external connection lands which is formed so as to have a predetermined thickness, the mask having openings in positions where the external connection lands are formed.

As described above, a method for manufacturing the semiconductor device of the present invention is a method for forming each of the external connection terminals by the wire bonding method at the step of connecting the semiconductor chip and the base substrate by the wire bonding method.

This produces the effect that it is possible to provide a semiconductor device having a high connection yield and high connection reliability between the semiconductor device and a mounting substrate and between the semiconductor devices even when the semiconductor device, which attains a thin thickness and a high density, is warped, and to provide a layered type semiconductor device using the same, a base substrate and a semiconductor device manufacturing method.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

### INDUSTRIAL APPLICABILITY

According to the semiconductor device of the present invention, it is possible to provide a downsized semiconductor device having high density in which a loose connection cannot be easily caused. Therefore, the present invention can be widely used in electronic parts including every kind of storage devices such as a semiconductor device and in electronic/electric products using these parts.

1. A semiconductor device comprising:
a plurality of external connection lands arranged on a base substrate for an external connection terminal used for electrical connection with an external member,
wherein the external connection lands at different arrangement positions have different heights in accordance with one of or both of a warp of the base substrate and a warp of the semiconductor device which warp the base substrate or semiconductor device would have when mounted.

2. The semiconductor device according to claim 1, wherein:
the external connection lands are formed on a reverse surface of the base substrate which is reverse to that surface of the base substrate on which a semiconductor chip is provided.

3. The semiconductor device according to claim 1, wherein:
the external connection lands are formed on a surface of the base substrate where a semiconductor chip is provided.

4. The semiconductor device according to claim 1, wherein:
the external connection lands are formed of a copper foil pattern and by plating.

5. A semiconductor device comprising:
a plurality of external connection lands arranged on a base substrate for an external connection terminal used for electrical connection with an external member,
the external connection terminal being formed on at least one of the plurality of external connection lands and not being formed on all of the plurality of external connection lands.

6. The semiconductor device according to claim 5, wherein
the external connection terminal is formed on the external connection lands formed on a surface of the base substrate where a semiconductor chip is provided.

7. The semiconductor device according to claim 5, wherein
the external connection terminal is made from a solder paste.

8. The semiconductor device according to claim 5, wherein
the external connection terminal is made from a flux.

9. The semiconductor device according to claim 5, wherein
the external connection terminal is made from a wire bump.

10. The semiconductor device according to claim 5, wherein
a plurality of wire bumps are formed on at least one of the external connection lands.

11. A layered type semiconductor device, wherein
a semiconductor device according to claim 1 and another semiconductor device are electrically connected with each other and are stacked on each other.

12.-20. (canceled)
